(19) United States
(12) Patent Application Publication
(10) Pub. No.: US 2025/0113612 A1
(43) Pub. Date: Apr. 3, 2025

(54) ARRAY SUBSTRATE AND LIQUID CRYSTAL DISPLAY PANEL

(71) Applicants: Ordos Yuansheng Optoelectronics Co., Ltd., Ordos, Inner Mongolia (CN); BOE Technology Group Co., Ltd., Beijing (CN)

(72) Inventors: Yuxuan MA, Beijing (CN); Xinguo WU, Beijing (CN); Longlong CHEN, Beijing (CN); Ke XU, Beijing (CN); Bo MA, Beijing (CN); Bin LIU, Beijing (CN); Wenqiang LV, Beijing (CN); Chunsheng GUO, Beijing (CN)

(21) Appl. No.: 18/578,662

(22) PCT Filed: Dec. 1, 2022
(86) PCT No.: PCT/CN2022/135785

§ 371 Date: Jan. 11, 2024

(51) Int. Cl. H10D 86/40; G02F 1/1362; H10D 86/60

(52) U.S. Cl. CPC H10D 86/441; G02F 1/136286; H10D 86/60

(57) ABSTRACT

Provided is an array substrate, including a substrate, a plurality of gate lines, and a plurality of sub-pixels. The gate line includes a plurality of connection portions and a plurality of jumper portions, which are alternately arranged and disposed in different layers. The connection portion includes a connection line segment, a first adapter line segment, and a second adapter line segment. One end of the connection line segment is connected to the first adapter line segment, and the other end is connected to the second adapter line segment. One end of the jumper portion, between adjacent two connection portions, is connected to an end, going away from the connection line segment, of the first adapter line segment in one of the connection portions, and the other end is connected to an end, going away from the connection line segment, of the second adapter line segment in the other connection portion.

### CROSS-REFERENCE TO RELATED APPLICATION

The present disclosure is a U.S. national stage of international application No. PCT/CN2022/135785, filed on Dec. 1, 2022, the content of which is herein incorporated by reference in its entirety.

### TECHNICAL FIELD

The present disclosure relates to the field of display technologies, and in particular, relates to an array substrate and a liquid crystal display panel.

### BACKGROUND

Liquid crystal display panels dominate the current display market due to their advantages of small size, low power consumption, and no radiation.

### SUMMARY

Embodiments of the present disclosure provide an array substrate and a liquid crystal display panel. The technical solutions are as follows.

According to some embodiments of the present disclosure, an array substrate is provided. The array substrate includes:
a substrate;
a plurality of gate lines and a plurality of sub-pixels arranged in arrays, which are disposed on a side of the substrate, wherein a row of the sub-pixels is electrically connected to a same gate line; wherein
the gate line includes a plurality of connection portions and a plurality of jumper portions, wherein the plurality of connection portions and the plurality of jumper portions are alternately arranged, and the connection portions and the jumper portions are disposed in different layers; wherein
the connection portion includes a connection line segment, a first adapter line segment, and a second adapter line segment that are disposed in a same layer and made of a same material, wherein one end of the connection line segment is connected to the first adapter line segment and the other end of the connection line segment is connected to the second adapter line segment, and an extension direction of the connection line segment is intersected with an extension direction of the first adapter line segment and intersected with an extension direction of the second adapter line segment; and
for the jumper portion between adjacent two of the connection portions, one end of the jumper portion is connected to an end, going away from the connection line segment, of the first adapter line segment in one of the connection portions, and the other end of the jumper portion is connected to an end, going away from the connection line segment, of the second adapter line segment in the other of the connection portions, and an extension direction of at least a portion of the jumper portion is intersected with the extension direction of the connection line segment.

In some embodiments, in the connection portion, the first adapter line segment and the second adapter line segment are respectively disposed on two sides of the connection line segment.

In some embodiments, in the connection portion, the extension direction of the first adapter line segment is parallel to the extension direction of the second adapter line segment.

In some embodiments, in the connection portion, a length of the first adapter line segment is equal to a length of the second adapter line segment.

In some embodiments, in the connection portion, an included angle between the connection line segment and the first adapter line segment is greater than or equal to 90°.

In some embodiments, the array substrate further includes a plurality of data lines, a column of the sub-pixels being electrically connected to a same data line; wherein an orthographic projection of the data line on the substrate is not coincident with an orthographic projection of the jumper portion on the substrate.

In some embodiments, the data line and the jumper portion are disposed in a same layer and made of a same material.

In some embodiments, the jumper portion is a straight-line jumper portion whose extension direction is a rectilinear direction.

In some embodiments, the extension direction of the jumper portion is parallel to an extension direction of the data line.

In some embodiments, in adjacent two of the connection portions, a first gap is defined between the first adapter line segment in one of the connection portions and the second adapter line segment in the other of the connection portions, and in an extension direction of the data line, a second gap is defined between the connection line segment in one of the connection portions and the adjacent adapter line segment in the other of the connection portions; wherein a minimum width of the first gap is equal to a minimum width of the second gap.

In some embodiments, the jumper portion includes a first jumper line segment, a second jumper line segment, and a third jumper line segment between the first jumper line segment and the second jumper line segment; wherein one end of the third jumper line segment is connected to an end of the first jumper line segment, and the other end of the third jumper line segment is connected to an end of the second jumper line segment; and an end, going away from the third jumper segment, of the first jumper line segment is connected to the end, going away from the connection line segment, of the first adapter line segment in one of the connection portions, and an end, going away from the third jumper segment, of the second jumper line segment is connected to the end, going away from the connection line segment, of the second adapter line segment in the other of the connection portions.

In some embodiments, an extension direction of the third jumper line segment is parallel to the extension direction of the connection line segment, and an overlapped region is present between an orthographic projection of the third jumper line segment on the substrate and an orthographic projection of the connection line segment on the substrate; and/or, an extension direction of the first jumper line segment is parallel to the extension direction of the first adapter line segment in one of the connection portions, and an overlapped region is present between an orthographic projection of the first jumper line segment on the substrate and an orthographic projection of the first adapter line segment on the substrate; and/or, an extension direction of the second jumper line segment is parallel to the extension direction of the second adapter line segment in the other of the connection portions, and an overlapped region is present between an orthographic projection of the second jumper line segment on the substrate and an orthographic projection of the second adapter line segment on the substrate.

In some embodiments, the array substrate has a first via and a second via therein; wherein one end of the jumper portion is connected to the end, going away from the connection line segment, of the first adapter line segment in one of the connection portions through the first via, and the other end of the jumper portion is connected to the end, going away from the connection line segment, of the second adapter line segment in the other of the connection portions through the second via.

In some embodiments, a first bridge electrode is disposed at the end, going away from the connection line segment, of the first adapter line segment, an orthographic projection of the first via on the substrate is within an orthographic projection of the first bridge electrode on the substrate, and one end of the jumper portion is connected to the first bridge electrode through the first via; and a second bridge electrode is disposed at the end, going away from the connection line segment, of the second adapter line segment, an orthographic projection of the second via on the substrate is within an orthographic projection of the second bridge electrode on the substrate, and the other end of the jumper portion is connected to the second bridge electrode through the second via.

In some embodiments, chamfers are formed at corners of the first bridge electrode and the second bridge electrode.

In some embodiments, in the connection portion, fillets are formed at both a connection between the connection line segment and the first adapter line segment and a connection between the connection line segment and the second adapter line segment.

According to some embodiments of the present disclosure, a liquid crystal display panel is provided. The liquid crystal display panel includes an array substrate and a color film substrate that are arranged opposite to each other, and a liquid crystal layer between the array substrate and the color film substrate, wherein the array substrate is the array substrate as described above.

In some embodiments, the color film substrate includes a black matrix, wherein an orthographic projection of a jumper portion of the array substrate on the substrate is within an orthographic projection of the black matrix on the substrate.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a top view of a common array substrate;

FIG. 2 is a partially enlarged view of a single gate line in the array substrate illustrated in FIG. 1;

FIG. 3 is a top view of an array substrate according to some embodiments of the present disclosure;

FIG. 4 is a partially enlarged view of the array substrate illustrated in FIG. 3 at a position A;

FIG. 5 is a cross-line segmental view of film layers at a line B-B′ of the gate line illustrated in FIG. 4;

FIG. 6 is a schematic structural diagram of a connection portion in a gate line according to some embodiments of the present disclosure;

FIG. 7 is a schematic structural diagram of another connection portion in a gate line according to some embodiments of the present disclosure;

FIG. 8 is a schematic structural diagram of yet another connection portion in a gate line according to some embodiments of the present disclosure;

FIG. 9 is a partially enlarged view of a gate line according to some embodiments of the present disclosure;

FIG. 10 is a partially enlarged view of another gate line according to some embodiments of the present disclosure;

FIG. 11 is a partially enlarged view of yet another gate line according to some embodiments of the present disclosure;

FIG. 12 is a partially enlarged view of yet still another gate line according to some embodiments of the present disclosure; and

FIG. 13 is a schematic structural diagram of film layers at a line C-C′ of the array substrate illustrated in FIG. 3.

### DETAILED DESCRIPTION

The present disclosure is described in further detail with reference to the accompanying drawings, to clearly present the objects, technical solutions, and advantages of the present disclosure.

Typically, a liquid crystal display panel includes an array substrate and a color film substrate that are disposed opposite to each other, and a liquid crystal layer sandwiched therebetween. A plurality of sub-pixels arranged in arrays, a plurality of gate lines, and a plurality of data lines are integrated within the array substrate. Each of the sub-pixels includes a thin film transistor (TFT) and a pixel electrode electrically connected to a first electrode of the TFT. A gate electrode of each TFT in a row of sub-pixels is electrically connected to the same gate line, and a second electrode of each TFT in a column of sub-pixels is electrically connected to the same data line.

However, in a large liquid crystal display panel, the gate line within the array substrate is long. During manufacturing of the array substrate, the long gate line is highly likely to adsorb electric charges, such that electrostatic breakdown occurs in the array substrate, and thus the yield of the array substrate is low.

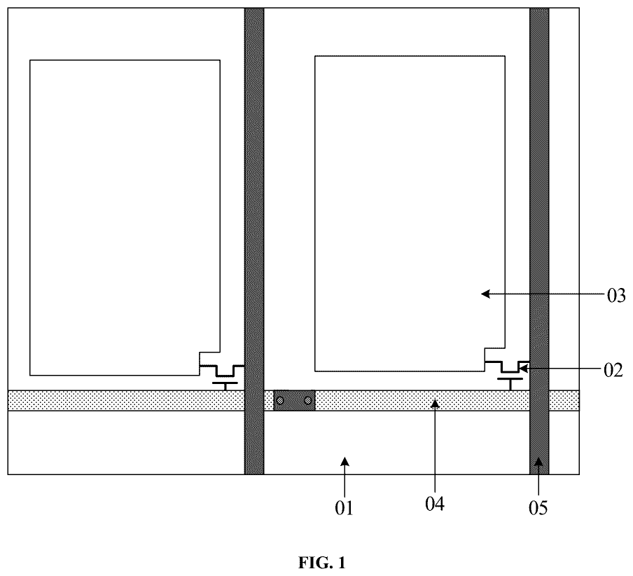

FIG. 1 is a top view of a common array substrate. The array substrate typically includes a substrate 01 and a plurality of sub-pixels arranged in arrays on a side of the substrate 01. The sub-pixel includes a thin film crystal transistor TFT 02 and a pixel electrode 03. A plurality of gate lines 04 and a plurality of data lines 05 are also typically integrated within the array substrate.

Each of the gate lines 04 is electrically connected to a gate electrode of each TFT 02 in the same row of sub-pixels. Each of the data lines 05 is electrically connected to a first electrode of each TFT 02 in the same column of sub-pixels. A second electrode of the TFT 02 in each of the sub-pixels is electrically connected to the pixel electrode 03. The TFT 02 in each of the sub-pixels further includes an active layer insulated from the gate line 04, and the active layer of the TFT 02 is electrically connected to source and drain electrodes.

In the manufacturing process of the array substrate, in the case that the gate line 04 is formed on the substrate 01 using a patterning process, the exposed gate line 04 is highly susceptible to collecting electric charges, which, for example, charged particles generated when plasma etching is performed. Moreover, the longer the gate line 04 is, the more charge is collected by the gate line 04, and the higher the potential of the gate line 04 is. Thus, the high potential of the gate line 04 is highly likely to breakdown a gate insulator layer used to insulate the gate line 04 and the active layer in the TFT 02, and a short circuit occurs between the gate line 04 and the active layer of the TFT 02. As a result, the yield of a large-sized array substrate is low.

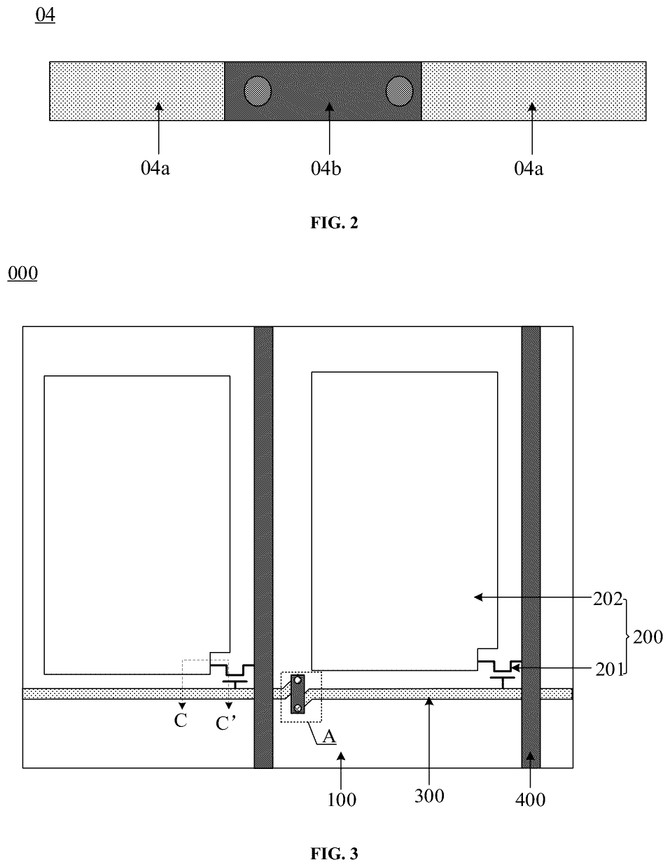

For a high yield of the array substrate, reference is made to FIG. 2, which is a partially enlarged view of a single gate line in the array substrate illustrated in FIG. 1. A plurality of partitions are arranged on the gate line 04 to divide the gate line 04 into a plurality of sub-gate line segments 04a, and a jumper 04b is employed to connect every adjacent two sub-gate line segments 04a in the gate line 04. An extension direction of the jumper 04b is parallel to an extension direction of the sub-gate line segment 04a, and the jumper 04b and the sub-gate line segment 04a are disposed in different layers.

After the gate line 04 is formed on the substrate 01, the individual sub-gate line segments 04a are not connected to each other by dividing the gate line 04 into the plurality of sub-gate line segments 04a, such that a length of each of the sub-gate line segments 04a is ensured to be small. In this way, even though the gate line 04 still absorbs charges due to exposure, the potential of the sub-gate line segment 04 is lowered due to the small length thereof, such that it is less likely to breakdown the gate insulation layer within the array substrate. Subsequently, the jumper 04b is deployed to connect every adjacent two sub-gate line segments 04a as one, such that each of the sub-gate line segments 04a in a single gate line 04 are electrically connected, and thus signals are still transmitted properly over this gate line 04.

However, in the case that the extension direction of the jumper 04b is parallel to the extension direction of the sub-gate line segment 04a, a distance between adjacent two sub-pixels in an extension direction of the gate line 04 is large, and thus pixels per inch (PPI) of the array substrate is low.

FIG. 3 is a top view of an array substrate according to some embodiments of the present disclosure. Referring to FIG. 3, The array substrate 000 includes a substrate 10, a plurality of sub-pixels 200 arranged in arrays on a side of the substrate 100, and a plurality of gate lines 300.

A row of sub-pixels 200 is electrically connected to the same gate line 300. In the present disclosure, the array substrate 000 further includes a plurality of data lines 400 disposed on a side of the substrate 100. A column of sub-pixels 200 is electrically connected to the same data line 400.

In some embodiments, an overall extension direction of the gate line 300 is perpendicular to an overall extension direction of the data line 400. One of the sub-pixels 200 is within a region enclosed by adjacent two gate lines 300 and adjacent two data lines 400. Each of the sub-pixels 200 includes a TFT 201 and a pixel electrode 202. A gate electrode of each TFT 201 in a row of sub-pixels 200 is electrically connected to the same gate line 300. A first electrode of each TFT 201 in a column of sub-pixels 200 is electrically connected to the same data line 400. A second electrode of the TFT 201 in each of the sub-pixels 200 is electrically connected to the pixel electrode 202 in this sub-pixel 200. It should be noted that the first electrode of the TFT 201 refers to one of a source electrode and a drain electrode, and the second electrode of the TFT 201 refers to another of the source electrode and the drain electrode.

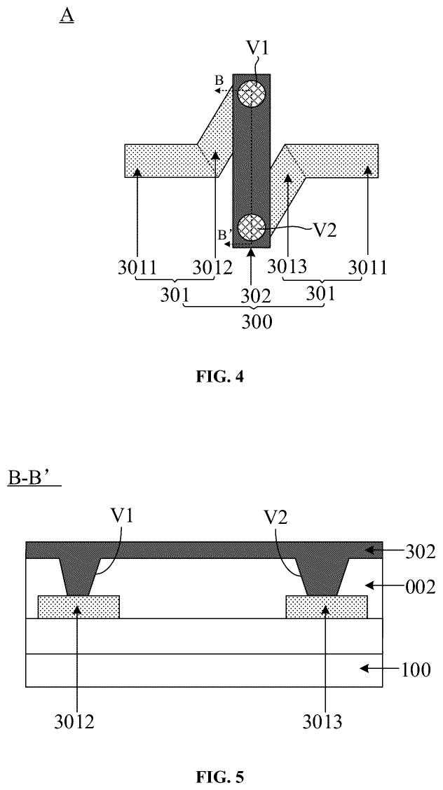

In some embodiments, for clearly view of the structure of the gate line 300 in the array substrate 000, reference is made to FIG. 4, a partially enlarged view of the array substrate illustrated in FIG. 3 at a position A. The gate line 300 in the array substrate 000 includes a plurality of connection portions 301 and a plurality of jumper portions 302. The plurality of connection portions 301 and the plurality of jumper portions 302 in the gate line 300 are alternately arranged, and the connection portions 301 and the jumper portions 302 are disposed in different layers.

It should be noted that two structures in the embodiments of the present disclosure disposed in different layers means: the two structures are disposed in different metal layers, and an insulator layer is sandwiched therebetween. For example, referring to FIG. 5, which is a cross-line segmental view of film layers at a line B-B′ of the gate line illustrated in FIG. 4, the connection portion 301 and the jumper portion 302 disposed in different layers means: a metal layer where the connection portion 301 is disposed is not the same layer as a metal layer where the jumper portion 302 is disposed, and an insulator layer sandwiched therebetween is an interlayer dielectric layer 002.

In the present disclosure, the connection portion 301 in the gate line 300 includes a connection line segment 3011, a first adapter line segment 3012, and a second adapter line segment 3013, which are arranged in the same layer and made of the same material. One end of the connection line segment 3011 in the connection portion 301 is connected to the first adapter line segment 3012, and the other end of the connection line segment 3011 is connected to the second adapter line segment 3013. An extension direction of the connection line segment 3011 in the connection portion 301 is intersected with an extension direction of the first adapter line segment 3012 and intersected with an extension direction of the second adapter line segment 3013.

It should be noted that adjacent two connection portions 301 illustrated in FIG. 4 are only partially illustrated. Taking the connection portion 301 illustrated in FIG. 4, which is disposed on the left side, as an example, the first adapter line segment 3012 is disposed at one end of the connection line segment 3011 in the connection portion 301, and the second adapter line segment 3013 is disposed at the other end of this connection line segment 3011.

It should also be noted that two structures in the present disclosure arranged in the same layer and made of the same material means: the two structures are disposed in the same metal layer and are formed at the same time by the same patterning process. For example, a metal layer where the connection line segment 3011 is disposed, a metal layer where the first adapter line segment 3012 is disposed, and a metal layer where the second adapter line segment 3013 is disposed are the same metal layer, and the connection line segment 3011, the first adapter line segment 3012, and the second adapter line segment 3013 are formed by the same patterning process.

It should also be added that extension directions of two line segments in the embodiments being intersected means: the extension directions of these two line segments are not parallel and an included angle between these two line segments is greater than 0° and less than 180°. For example, the extension direction of the connection line segment 3011 intersected with the extension direction of the first adapter line segment 3012 means: the extension direction of the connection line segment 3011 is not parallel to the extension direction of the first adapter line segment 3012, and an included angle between the connection line segment 3011 and the first adapter line segment 3012 is greater than 0° and less than 180°.

In some embodiments, for the jumper portion 302 between adjacent two connection portions 301, one end of the jumper portion 302 is connected to an end, going away from the connection line segment 3011, of the first adapter line segment 3012 in one of the connection portions 301, and the other end of the jumper portion 302 is connected to an end, going away from the connection line segment 3011, of a second adapter line segment 3013 in the other of the connection portions 301, and an extension direction of at least of a portion of the jumper portion 302 is intersected with the extension direction of the connection line segment 3011.

In some embodiments, as illustrated in FIG. 4 and FIG. 5, because the connection portion 301 and the jumper portion 302 are disposed in different layers, a first via V1 and a second via V2 need to be defined in the array substrate 000 to properly connect the connection portion 301 to the jumper portion 302. For example, the interlayer dielectric layer 002 is provided between the metal layer where the connection portion 301 is disposed and the metal layer where the jumper portion 302 is disposed, and the first via V1 and the second via V2 of the array substrate 000 are defined within the interlayer dielectric layer 00. In this way, one end of the jumper portion 302 is connected to the first adapter line segment 3012 in one of the connection portions 301 through the first via V1, and the other end of the jumper portion 302 is connected to the second adapter line segment 3013 in the other of the connection portions 301 through the second via V2.

The jumper portion 302 is disposed between every adjacent two connection portions 301 in the gate line 300, and the jumper portions 302 and the connection portions 301 are disposed in different layers. Therefore, after the connection portion 301 in the gate line 300 is formed on the substrate 100, the adjacent two connection portions 301 are not connected to each other, such that a length of each of the connection portions 301 is ensured to be small, and thus a potential of the connection portion 301 is effectively lowered. In this case, even though the connection portion 301 in the gate line 300 still absorbs charges due to exposure, it is less likely to breakdown the insulator layer within the array substrate 300, and thus the yield of the array substrate 000 is effectively improved. Subsequently, the jumper portion 302, which is disposed in the layer different from the layer where the connection portion 301 is disposed, is deployed to connect every adjacent two connection portions 301 as one, such that the individual connection portions 301 in the gate line 300 are electrically connected, and thus signals are still transmitted normally over this gate line 300.

Furthermore, because the extension direction of the connection line segment 3011 in the connection portion 301 is intersected with the extension direction of the first adapter line segment 3012 and intersected with the extension direction of the second adapter line segment 3013, the extension direction of the jumper portion 302 is ensured to be intersected with the extension direction of the connection line segment 3011 in the connection portion 301 in connecting adjacent two connection portions 301 as one by the jumper portion 302. In this way, a width of the jumper portion 302 in a direction parallel to the connection line segment 3011 is effectively reduced, such that a distance between adjacent two sub-pixels 200 is small in an overall extension direction of the gate line 300. Therefore, PPI of the array substrate 000 are ensured to be high, and thus the liquid crystal display panel integrated with such an array substrate 000 is ensured to have a good display effect.

In summary, some embodiments of the present disclosure provide an array substrate. The array substrate includes the substrate, and the plurality of gate lines and the plurality of sub-pixels that are disposed on a side of the substrate. The jumper portion is disposed between every adjacent two connection portions in the gate lines, and the jumper portions and the connection portions are disposed in different layers. Therefore, after the connection portions in the gate lines are formed on the substrate, every adjacent two connection portions are not connected to each other, such that the length of each of the connection portions is ensured to be small, and thus the potentials of the connection portions are lowered. In this way, even though the connection portions in the gate lines still absorb charges due to exposure, it is less likely to breakdown the insulator layer within the array substrate, and thus the yield of the array substrate is effectively improved. Moreover, because the extension direction of the connection line segment in the connection portion is intersected with the extension direction of the first adapter line segment and intersected with the extension direction of the second adapter line segment, the extension direction of the jumper portion is ensured to be intersected with the extension direction of the connection line segment in the connection portion in connecting adjacent two connection portions as one by the jumper portion. Therefore, the width of the jumper portion in the direction parallel to the connection line segment is effectively reduced, such that the distance between adjacent two sub-pixels in the overall extension direction of the gate line is small. In this way, the PPI of the array substrate are ensured to be high, and thus the display effect of the liquid crystal display panel integrated with such an array substrate is ensured to be good.

It should be noted that the array substrate 000 in the embodiments has a display region and a non-display region disposed on a periphery of the display region. Most of the gate lines 300 in the array substrate 000 need to be distributed within the display region, and a small portion of the gate lines 300 are distributed in the non-display region. The connection portion 301 and the jumper portion 302 in the gate line 300 are both within the display region, while the portion, within the non-display region, of the gate line 300 is not provided with the jumper structure.

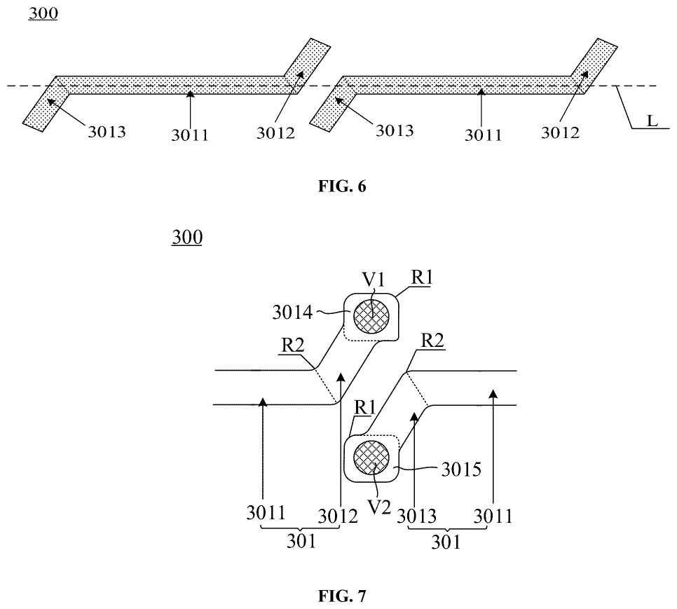

In some embodiments, as illustrated in FIG. 6, which is a schematic structural diagram of a connection portion in a gate line according to some embodiments of the present disclosure, the connection line segments 3011 in the connection portions 301 of the gate line 300 are collinear. That is, center lines L of the connection line segments 3011 in the connection portions 301 are collinear.

In the present disclosure, as illustrated in FIG. 6, in each of the connection portions 301 of the gate line 300, the first adapter line segment 3012 and the second adapter line segment 3013 are respectively disposed on two sides of the connection line segment 3011. In this way, in adjacent two connection portions 301, an end, going away from the connection line segment 301, of the first adapter line segment 3012 in one of the connection portions 301 is disposed on one side of the center line L, and an end, going away from the connection line segment 3011, of the second adapter line segment 3013 in the other of the connection portions 301 is disposed on the other side of the center line L. In this way, in connecting both ends of the jumper portion 302 to these two ends, the extension direction of at least a portion of the jumper portion 302 is ensured to be intersected with the extension direction of the connection line segment 3011.

In some embodiments, as illustrated in FIG. 6, in each of the connection portions 301 of the gate line 300, the extension direction of the first adapter line segment 3012 is parallel to the extension direction of the second adapter line segment 3013. That is, an included angle between the first adapter line segment 3012 and the connection line segment 3011 is equal to an included angle between the second adapter line segment 3013 and the connection line segment 3011. In some other embodiments, the extension direction of the first adapter line segment 3012 is not parallel to the extension direction of the second adapter line segment 3013, such that the included angle between the first adapter line segment 3012 and the connection line segment 3011 is different from and the included angle between the second adapter line segment 3013 and the connection line segment 3011, but a difference between the two angles is small. For example, the difference is less than or equal to 100.

In some embodiments, as illustrated in FIG. 6, in each of the connection portions 301 of the gate line 300, a length of the first adapter line segment 3012 is equal to a length of the second adapter line segment 3013

In some embodiments, as illustrated in FIG. 6, in each of the connection portions 301 of the gate line 300, a width of the connection line segment 3011 is equal to a width of the first adapter line segment 3012 and equal to a width of the second adapter line segment 3013.

In this case, the connection portions 301 in the gate line 300 are ensured to have the same structure, and the connection portions 301 in the gate line 300 are ensured to be evenly distributed. In this way, a process difficulty in forming the connection portions 301 in the gate line 300 by the patterning process is effectively simplified, and the yield in forming the connection portions 301 is ensured to be high.

In some embodiments, the included angle between the connection line segment 3011 and the first adapter line segment 3012 in each of the connection portions 301 of the gate line 300 is an acute angle, a right angle, or an obtuse angle.

In some embodiments, in each of the connection portions 301 of the gate line 300, the included angle between the connection line segment 3011 and the first adapter line segment 3012 is greater than or equal to 90°.

In some embodiments, in each of the connection portions 301 of the gate line 300, the included angle between the connection line segment 3011 and the first adapter line segment 3012 is less than or equal to 140°.

Exemplarily, under the prerequisite that the included angle between the connection line segment 3011 and the first adapter line segment 3012 is greater than or equal to 900 and less than or equal to 140°, in the case adjacent two connection portions 301 are connected by the jumper portion 302 in the gate line 300, an included angle between the extension direction of the jumper portion 302 and an overall extension direction perpendicular to the gate line 300 is ensured to be small, such that the width of the jumper portion 302 in the overall extension direction of the gate line 300 is further reduced, an thus the PPI of the array substrate 000 is further improved

In some embodiments, the data line 400 is provided within the array substrate 000, and the data line 400 is disposed in a layer different from the layer where the connection portion 301 in the gate line 300 is disposed. Therefore, to simplify the difficulty in preparing the array substrate 000, it is possible to cause the jumper portion 302 in the gate line 300 and the data line 400 to be arranged in the same layer and made of the same material. In this way, the jumper portion 302 in the gate line 300 and the data line 400 are formed at the same time by a one-time patterning process. The one-time patterning process involves photoresist coating, exposure, development, etching, and photoresist stripping.

It should be noted that to avoid a short circuit between the gate line 300 and the data line 400, the gate line 300 needs to be insulated from the data line 400. Because the metal layer where the connection portion 301 in the gate line 300 is disposed is different from the metal layer where the data line 400 is disposed, the connection portion 301 in the gate line 300 and the data line 400 are insulated from each other by an insulator layer between these two metal layers. Furthermore, because the metal layer where the jumper portion 302 in the gate line 300 is disposed is the same as the metal layer where the data line 400 is disposed, an orthographic projection of the jumper portion 302 on the substrate 100 needs to be not coincident with an orthographic projection of the data line 400 on the substrate 100, such that the jumper portion 302 and the data line 400 are ensured to be insulated from each other.

In some embodiments, as illustrated in FIG. 7, which is a schematic structural diagram of another connection portion in a gate line according to some embodiments of the present disclosure, the connection portion 301 and the jumper portion 302 in the gate line 300 need to be connected through the vias (i.e., the first via V1 and the second via V2). Therefore, to ensure a large bridging area between the connection portion 301 and the jumper portion 302 for a better electrical connection therebetween, a bridge electrode is provided at an end, going away from the connection line segment, of the adapter line segment in the connection portion 301.

Exemplarily, a first bridge electrode 3014 is disposed at an end, going away from the connection line segment 3011, of the first adapter line segment 3012 in the connection portion 301, and an orthographic projection of the first via V1 on the substrate 100 is within an orthographic projection of the first bridge electrode 3014 on the substrate 100, such that one end of the jumper portion 302 is connected to the first bridge electrode 3014 through the first via V1. In this way, a bridging area of this end when connected to one end of jumper portion 302 is increased by the first bridge electrode 3014.

Similarly, a second bridge electrode 3015 is disposed at an end, going away from the connection line segment 3011, of the second adapter line segment 3013 in the connection portion 301, and an orthographic projection of the second via V2 on the substrate 100 is within an orthographic projection of the second bridge electrode 3015 on the substrate 100, such that the other end of the jumper portion 302 is connected to the second bridge electrode 3015 through the second via V2. In this way, a bridging area of this end when connected to the other end of the jumper portion 302 is increased by the second bridge electrode 3015.

In some embodiments, the orthographic projections of the first bridge electrode 3014 and the second bridge electrode 3015 in the connection portion 301 on the substrate 100 are both in the shape of a square. To reduce the probability that corners of the first bridge electrode 3014 and the second bridge electrode 3015 are susceptible to point discharge, chamfers R1 are formed at the corners of the first bridge electrode 3014 and the second bridge electrode 3015. By the chamfers R1 at the corners of the first bridge electrode 3014, the point discharge at the corners of the first bridge electrode 3014 is effectively avoided, and by the chamfers R1 at the corners of the second bridge electrode 3015, the point discharge of the corners of the second bridge electrode 3015 is effectively avoided, such that a probability that an electrostatic discharge (ESD) phenomenon occurs to the array substrate 000 is reduced.

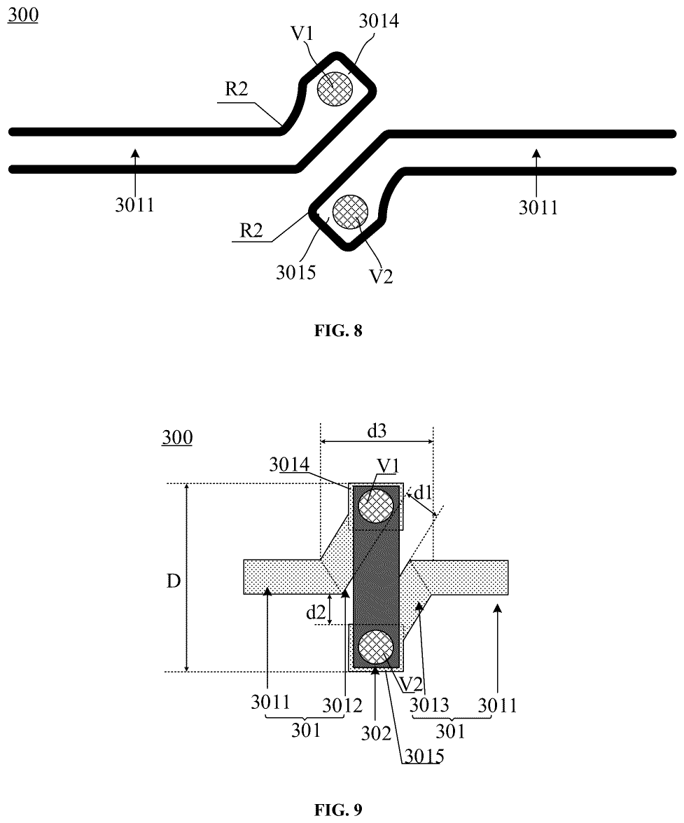

It should be noted that exposure by an exposure machine is required in the process of forming each of the connection portions 301 by the patterning process, and the exposure machine has an exposure accuracy. Therefore, as illustrated in FIG. 8, which is a schematic structural diagram of yet another connection portion in a gate line according to some embodiments of the present disclosure, in the case that the exposure accuracy of the exposure machine is low, the corners of the first bridge electrode 3014 and the second bridge electrode 3015 are cut, such that orthographic projections of the corners of the first bridge electrode 3014 and the second bridge electrode 3015 on the substrate 100 are both in the shape of a diamond. It should be understood that in the case that the exposure accuracy of the exposure machine is high, the corners of the first bridge electrode 3014 and the second bridge electrode 3015 are still retained, and both of these corners have the chamfers R1.

In some embodiments, as illustrated in FIGS. 7 and 8, in each of the connection portions 301 of the gate line 300, fillets R2 are formed at both a connection between the connection line segment 3011 and the first adapter line segment 3012 and a connection between the connection line segment 3011 to the second adapter line segment 3013. A connection between a side edge of the connection line segment 3011 and a side edge of the first adapter line segment 3012 is a curved side edge. In this case, by the fillets R2 at the connection between the connection line segment 3011 and the adapter line segment in the connection portion 301, the point discharge between adjacent two connection portions 301 is effectively avoided, and thus the probability that the ESD phenomenon occurs to the array substrate 000 is further reduced.

It should be noted that an optical diffraction phenomenon occurs during the process of exposing the connection between the connection line segment 3011 and the adapter line segment in the connection portion 301 and the corner of the bridge electrode by the exposure machine. Therefore, upon the completion of the patterning process, the connection between the connection line segment 3011 and the adapter line segment and each of the corners of the bridge electrode are round, such that the fillets R2 are formed at the connection between the connection line segment 3011 and the adapter line segment, and the chamfers R1 are formed at the corners of the bridge electrode.

In the present disclosure, as illustrated in FIG. 9, which is a partially enlarged view of a gate line according to some embodiments of the present disclosure, in adjacent two connection portions 301, a first gap d1 is defined between the first adapter line segment 3012 in one of the connection portions 301 and the second adapter line segment 3013 in the other of the connection portions 301. In the extension direction of the data line 400, a second gap d1 is defined between the connection line segment 3011 in one of the connection portions 301 and an adjacent adapter line segment (i.e., the first adapter line segment 3012 or the second adapter line segment 3013). Because the adapter line segment has the bridge electrode at its end, the second gap d2 refers to a gap between the connection line segment 3011 and the bridge electrode.

At least one of a width of the first gap d1, a width of the second gap d2, and a dimension of the via V affects a width d3 of a jumper structure in the overall extension direction of the gate line 300. The jumper structure herein refers to a distance between two connection line segments 3011 in adjacent two connection portions 301.

In some embodiments, the smaller the width of the first gap d1 is, the smaller the width d3 of the jumper structure in the overall extension direction of the gate line 300 is; the smaller the width of the second gap d2 is, the smaller the width d3 of the jumper structure in the overall extension direction of the gate line 300 is; and the smaller the dimension of the via V is, the smaller the width d3 of the jumper structure in the overall extension direction of the gate line 300 is.

It should be noted that the width of the first gap d1, the width of the second gap d2, and the dimension of the via V all need to be greater than or equal to a predetermined width. The predetermined width is related to the exposure accuracy during the process of performing the patterning process. That is, the higher the exposure accuracy, the smaller the predetermined width, and the lower the exposure accuracy, the larger the predetermined width.

It should also be noted that the width d3 of the jumper structure in the overall extension direction of the gate line 300 is also related to an alignment accuracy of the film layers in the array substrate 000. For example, the width d3 is related to an alignment accuracy of the metal layer where the connection portion 301 is disposed, an alignment accuracy of the via V, and an alignment accuracy of the metal layer where the jumper portion 302 is disposed. The higher the alignment accuracy of the film layer, the smaller the width d3 of the jumper portion 302 in the overall extension direction of the gate line 300.

In the present disclosure, there are various structures of the jumper portion 302 in the gate line 300. The width d3 of the jumper structure in the overall extension direction of the gate line 300 is illustrated hereinafter using various optional examples.

In a first optional example, as illustrated in FIG. 9, the jumper portion 302 in the gate line 300 is a straight-line jumper portion whose extension direction is a rectilinear direction.

It should be noted that in the case that the jumper portion 302 in the gate line 300 is a straight-line jumper portion, the extension direction of the jumper portion 302 is related to the included angle between the connection line segment 3011 and the first adapter line segment 3012 in the connection portion 301. Accordingly, the embodiments of the present disclosure give the description hereinafter using three examples as follows.

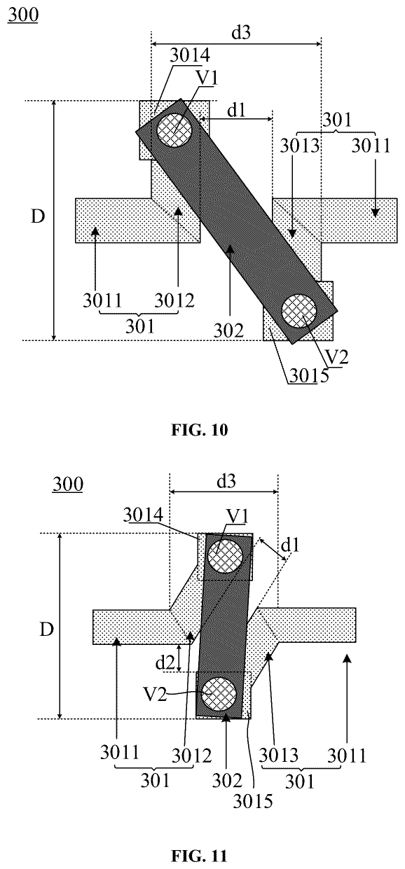

In a first example, as illustrated in FIG. 10, which is a partially enlarged view of another gate line according to some embodiments of the present disclosure, in the case that the included angle between the connection line segment 3011 and the first adapter line segment 3012 in the connection portion 301 is a right angle, the extension direction of the jumper portion 302 in the gate line 300 is intersected with the extension direction of the data line 400, and the jumper portion 302 in the gate line 300 deflects towards the first adapter line segment 3012.

In this example, the width d3 of the jumper structure in the overall extension direction of the gate line 300 is related to the width of the first gap d1 and the dimension of the via V.

In a second example, as illustrated in 9, in the case that the included angle between the connection line segment 3011 and the first adapter line segment 3012 in the connection portion 301 is an obtuse angle, where an end of the first adapter line segment 3012 of one of adjacent two connection portions 300 is flush, in the overall extension direction of the gate line 300, with an end of the second adapter line segment 3013 of the other of the adjacent two connection portions 301, the extension direction of the jumper portion 302 in the gate line 300 is parallel to the extension direction of the data line 400.

In this example, the width d3 of the jumper structure in the overall extension direction of the gate line 300 is related to the width of the first gap d1, the width of the second gap d2, and the dimension of the via V. The width of the first gap d1 herein is greater than the width of the second gap d2.

It should be noted that in the case that the extension direction of the jumper portion 302 in the gate line 300 is parallel to the extension direction of the data line 400, the included angle between the extension direction of the jumper portion 302 and the overall extension direction that is perpendicular to the gate line 300 is ensured to be 0, such that the width d3 of the jumper structure in the overall extension direction of the gate line 300 in such a case is less than that in the first case.

In a third example, as illustrated in FIG. 11, which is a partially enlarged view of yet another gate line according to some embodiments of the present disclosure, in the case that the included angle between the connection line segment 3011 and the first adapter line segment 3012 in the connection portion 301 is an obtuse angle, where a minimum width of the first gap d1 is equal to a minimum width of the second gap d2, the extension direction of the jumper portion 302 in the gate line 300 is intersected with the extension direction of the data line 400, and the jumper portion 302 in the gate line 300 deflects towards the second adapter line segment 3013.

In this example, the width d3 of the jumper structure in the overall extension direction of the gate line 300 is related to the width of the first gap d1, the width of the second gap d2, and the dimension of the via V.

It should be noted that in the case that the minimum width of the first gap d1 is equal to the minimum width of the second gap d2, the jumper portion 302 in the gate line 300 deflects towards the second adapter line segment 3013 at a smaller angle, such that the width d3 of the jumper structure in the overall extension direction of the gate line 300 in such a case is further reduced relative to that in the second case.

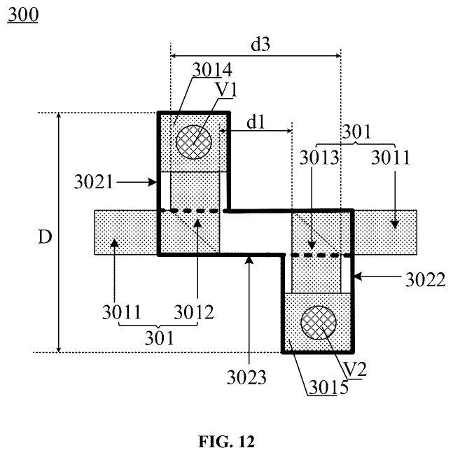

In a second optional example, as illustrated in FIG. 12, which is a partially enlarged view of yet still another gate line according to some embodiments of the present disclosure, the jumper portion 302 in the gate line 300 is a fold-line jumper portion whose extension direction in a folded direction.

In some embodiments, the jumper portion 302 in the gate line 300 includes a first jumper line segment 3021, a second jumper line segment 3022, and a third jumper line segment 3023 between the first jumper line segment 3021 and the second jumper line segment 3022. One end of the third jumper line segment 3023 is connected to an end of the first jumper line segment 3021, and the other end of the third jumper line segment 3023 is connected to an end of the second jumper line segment 3022. An end, going away from the third jumper line segment 3023, of the first jumper line segment 3021 is connected to an end of the first adapter line segment 3012 in one of the connection portions 301, and an end, going away from the third jumper line segment 3023, of the second jumper line segment 3022 is connected to an end of the second adapter line segment 3013 in the other of the connection portions 301.

In the present disclosure, an extension direction of the third jumper line segment 3023 in the jumper portion 302 is parallel to the extension direction of the connection line segment 3011, and an overlapped region is present between an orthographic projection of the third jumper line segment 3023 on the substrate 100 and an orthographic projection of the connection line segment 3011 on the substrate 100; and/or
an extension direction of the first jumper line segment 3021 in the jumper portion 302 is parallel to the extension direction of the first adapter line segment 3012 in one of the connection portions 301, and an overlapped reign is present between an orthographic projection of the first jumper line segment 3021 on the substrate 100 and an orthographic projection of the first adapter line segment 3012 on the substrate 100; and/or
an extension direction of the second jumper line segment 3022 in the jumper portion 302 is parallel to the extension direction of the second adapter line segment 3013 in the other of the connection portions 301, and an overlapped region is present between an orthographic projection of the second jumper line segment 3022 on the substrate 100 and an orthographic projection of the second adapter line segment 3013 on the substrate 100.

In this case, the orthographic projection of the jumper portion 302 on the substrate 100 is overlapped with the orthographic projections of both adjacent two connection portions 301 on the substrate 100. Both the jumper portion 302 and the connection portions 301 are made of a light-impermeable metallic material. Therefore, in the case that the orthographic projection of the jumper portion 302 on the substrate 100 and the orthographic projection of the connection portion 301 on the substrate 100 have the overlapped region, the array substrate 000 is ensured to have a high transmittance of light.

It should be noted that FIG. 12 gives the description using a scenario where the included angle between the connection line segment 3011 and the first adapter line segment 3012 in the connection portion 301 is a right angle as an example. In this case, the width of the jumper portion 302 in the overall extension direction of the gate line 300 is equal to the width in the first case described above. In other examples, the included angle between the connection line segment 3011 and the first adapter line segment 3012 in the connection portion 301 is an obtuse or an acute angle, which is not repeated herein.

In some embodiments, the plurality of connection line segments 3011 in each of the gate lines 300 in one-to-one correspondence to the plurality of sub-pixels 200 in a row of sub-pixels 200, and each of the connection line segments 3011 is electrically connected to the gate electrode of the TFT 201 in the corresponding sub-pixel 200. In this case, the jumper portion 302 used to connect adjacent two connection portions 301 are disposed between adjacent two sub-pixels 200.

In some embodiments, in the case that the array substrate 000 according to the embodiments of the present disclosure is integrated within an LCD panel, a transverse black matrix arranged within the LCD panel needs to shield the gate lines 300, and a longitudinal black matrix arranged within the LCD panel needs to shield the data lines 400. For this reason, as illustrated in FIG. 7 to FIG. 10, to ensure that the transverse black matrix shields all the gate lines 300, the width of the jumper portion 302 in the gate line 300 in the extension direction of the data line 400 needs to be less than a width of the transverse black matrix.

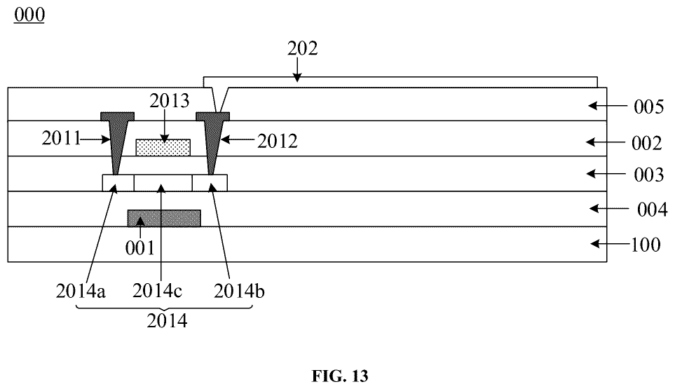

In some embodiments, as illustrated in FIG. 13, which is a schematic structural diagram of film layers at a line C-C′ of the array substrate illustrated in FIG. 3, the TFT 201 includes a first electrode 2011, a second electrode 2012, a gate electrode 2013, and an active layer 2014. The first electrode 2011 of the TFT 201 is electrically connected to the pixel electrode 202, the second electrode 2012 of the TFT 202 is electrically connected to the data line 400, and the gate electrode 2013 of the TFT 202 is electrically connected to the gate line 300.

The active layer 2014 of the TFT 201 is electrically connected to the first electrode 2011 and the second electrode 2012. Exemplarily, the active layer 2014 has a first region 2014a configured to be connected to the first electrode 2011, a second region 2014b configured to be connected to the second electrode 2012, and a channel region 2014c between the first region 2014a and the second region 2014b.

The active layer 2014 of the TFT 201 is insulated from the gate electrode 2013. Exemplarily, a gate insulator layer 003 is provided between the active layer 2014 and the gate electrode 2013. An overlapped region is present between an orthographic projection of the gate electrode 2013 on the substrate 100 and an orthographic projection of the channel region 2014c of the active layer 2014 on the substrate 100.

It should be noted that the embodiments of the present disclosure give the description using a scenario where the active layer 2014 in the TFT 201 is closer to the substrate 100 than the gate electrode 2013, i.e., the TFT 201 is a top-gate TFT, as an example. In some other embodiments, the TFT 201 is a bottom-gate TFT, which is not limited herein.

It should also be noted that in the case that the TFT 201 is a top-gate TFT, an interlayer dielectric layer 002 is provided between a metal layer where the gate electrode 2013 of the TFT 201 is disposed and a metal layer where the first electrode 2011 and the second electrode 2012 of the TFT 201 are disposed.

In some embodiments, the array substrate 000 further includes a light-shielding layer 001 disposed on a side, proximal to the substrate 100, of the TFT 201. An orthographic projection of the channel region 2014c of the active layer 2014 in the TFT 201 on the substrate 100 is within an orthographic projection of the light-shielding layer 001 on the substrate 100. In this way, light incident into the channel region 2014c is effectively reduced by the light-shielding layer 001, such that the electrical property of the TFT 201 is good.

In the present disclosure, the array substrate 000 further includes a buffer layer 004 disposed on a side, going away from the substrate 100, of the light-shielding layer 001.

In some embodiments, the array substrate 000 further includes an insulator protection layer 005 disposed on a side, going away from the substrate 100, of the TFT 201. The pixel electrode 203 is disposed on a side, going away from the substrate 100, of the insulator protection layer 005.

In summary, some embodiments of the present disclosure provide an array substrate. The array substrate includes the substrate, and the plurality of gate lines and the plurality of sub-pixels that are disposed on a side of the substrate. The jumper portion is disposed between every adjacent two connection portions in the gate lines, and the jumper portions and the connection portions are disposed in different layers. Therefore, after the connection portions in the gate lines are formed on the substrate, every adjacent two connection portions are not connected to each other, such that the length of each of the connection portions is ensured to be small, and thus the potentials of the connection portions are lowered. In this way, even though the connection portion in the gate lines still absorbs charges due to exposure, it is less likely to breakdown the insulator layer within the array substrate, and thus the yield of the array substrate is effectively improved. Moreover, because the extension direction of the connection line segment in the connection portion is intersected with the extension direction of the first adapter line segment and intersected with the extension direction of the second adapter line segment, the extension direction of the jumper portion is ensured to be intersected with the extension direction of the connection line segment in the connection portion in connecting adjacent two connection portions as one by the jumper portion. Therefore, the width of the jumper portion in the direction parallel to the connection line segment is effectively reduced, such that the distance between adjacent two sub-pixels in the overall extension direction of the gate lines is small. In this way, the PPI of the array substrate are ensured to be high, and thus the display effect of the liquid crystal display panel integrated with such an array substrate is ensured to be good.

Some embodiments of the present disclosure further provide a liquid crystal display panel. The liquid crystal display panel includes an array substrate and a color film substrate that are arranged opposite each other, and a liquid crystal layer disposed between the array substrate and the color film substrate. The array substrate is an array substrate illustrated in the above embodiments. For example, the array substrate is the array substrate illustrated in FIG. 3.

In some embodiments, the color film substrate has a black matrix, and an orthographic projection of the jumper portion of the array substrate on the substrate is within an orthographic projection of the black matrix on the substrate.

Some Embodiments of the present disclosure further provide a display device, which is a smartphone, a tablet computer, a television, a monitor, a laptop computer, a digital photo frame, a navigator, and any other product or component having a display function. The display device includes a liquid crystal display panel in the above embodiments and a backlight source. The backlight source is disposed on a side, going away from the color film substrate, of the array substrate.

It should be noted that in the accompanying drawings, the sizes of layers and regions may be exaggerated for clearer illustration. It should be understood that where an element or layer is referred to as being “on” another element or layer, the element or layer may be directly on another element, or intervening layers therebetween may be present. In addition, it should be understood that where an element or layer is referred to as being “under” another element or layer, the element or layer may be directly under the other element, or there may be more than one intervening layer or element. In addition, it may be further understood that in the case that a layer or element is referred to as being “between” two layers or two elements, the layer may be the only layer between the two layers or two elements, or more than one intervening layer or element may further be present. Like reference numerals indicate like elements throughout.

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements).

In the present disclosure, the terms “first” and “second” are only used for descriptive purposes, and cannot be understood as indicating or implying relative importance. The term “a plurality of” refers to two or more, unless expressly defined otherwise.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. An array substrate, comprising:
a substrate;
a plurality of gate lines and a plurality of sub-pixels arranged in arrays, which are disposed on a side of the substrate, wherein a row of the sub-pixels is electrically connected to a same gate line; wherein
the gate line comprises a plurality of connection portions and a plurality of jumper portions, wherein the plurality of connection portions and the plurality of jumper portions are alternately arranged, and the connection portions and the jumper portions are disposed in different layers; wherein
the connection portion comprises a connection line segment, a first adapter line segment, and a second adapter line segment that are disposed in a same layer and made of a same material, wherein one end of the connection line segment is connected to the first adapter line segment and the other end of the connection line segment is connected to the second adapter line segment, and an extension direction of the connection line segment is intersected with an extension direction of the first adapter line segment and intersected with an extension direction of the second adapter line segment; and
for the jumper portion between adjacent two of the connection portions, one end of the jumper portion is connected to an end, going away from the connection line segment, of the first adapter line segment in one of the connection portions, and the other end of the jumper portion is connected to an end, going away from the connection line segment, of the second adapter line segment in the other of the connection portions, and an extension direction of at least a portion of the jumper portion is intersected with the extension direction of the connection line segment.

2. The array substrate according to claim 1, wherein in the connection portion, the first adapter line segment and the second adapter line segment are respectively disposed on two sides of the connection line segment.

3. The array substrate according to claim 2, wherein in the connection portion, the extension direction of the first adapter line segment is parallel to the extension direction of the second adapter line segment.

4. The array substrate according to claim 3, wherein in the connection portion, a length of the first adapter line segment is equal to a length of the second adapter line segment.

5. The array substrate according to claim 4, wherein in the connection portion, an included angle between the connection line segment and the first adapter line segment is greater than or equal to 90°.

6. The array substrate according to claim 1, further comprising: a plurality of data lines, a column of the sub-pixels being electrically connected to a same data line;
wherein an orthographic projection of the data line on the substrate is not coincident with an orthographic projection of the jumper portion on the substrate.

7. The array substrate according to claim 6, wherein the data line and the jumper portion are disposed in a same layer and made of a same material.

8. The array substrate according to claim 7, wherein the jumper portion is a straight-line jumper portion whose extension direction is a rectilinear direction.

9. The array substrate according to claim 8, wherein the extension direction of the jumper portion is parallel to an extension direction of the data line.

10. The array substrate according to claim 8, wherein in adjacent two of the connection portions, a first gap is defined between the first adapter line segment in one of the connection portions and the second adapter line segment in the other of the connection portions, and in an extension direction of the data line, a second gap is defined between the connection line segment in one of the connection portions and the adjacent adapter line segment in the other of the connection portions;
wherein a minimum width of the first gap is equal to a minimum width of the second gap.

11. The array substrate according to claim 7, wherein the jumper portion comprises a first jumper line segment, a second jumper line segment, and a third jumper line segment between the first jumper line segment and the second jumper line segment; wherein
one end of the third jumper line segment is connected to an end of the first jumper line segment, and the other end of the third jumper line segment is connected to an end of the second jumper line segment; and
an end, going away from the third jumper segment, of the first jumper line segment is connected to the end, going away from the connection line segment, of the first adapter line segment in one of the connection portions, and an end, going away from the third jumper segment, of the second jumper line segment is connected to the end, going away from the connection line segment, of the second adapter line segment in the other of the connection portions.

12. The array substrate according to claim 11, wherein
an extension direction of the third jumper line segment is parallel to the extension direction of the connection line segment, and an overlapped region is present between an orthographic projection of the third jumper line segment on the substrate and an orthographic projection of the connection line segment on the substrate; and/or
an extension direction of the first jumper line segment is parallel to the extension direction of the first adapter line segment in one of the connection portions, and an overlapped region is present between an orthographic projection of the first jumper line segment on the substrate and an orthographic projection of the first adapter line segment on the substrate; and/or
an extension direction of the second jumper line segment is parallel to the extension direction of the second adapter line segment in the other of the connection portions, and an overlapped region is present between an orthographic projection of the second jumper line segment on the substrate and an orthographic projection of the second adapter line segment on the substrate.

13. The array substrate according to claim 1, having a first via and a second via therein; wherein
one end of the jumper portion is connected to the end, going away from the connection line segment, of the first adapter line segment in one of the connection portions through the first via, and the other end of the jumper portion is connected to the end, going away from the connection line segment, of the second adapter line segment in the other of the connection portions through the second via.

14. The array substrate according to claim 13, wherein
a first bridge electrode is disposed at the end, going away from the connection line segment, of the first adapter line segment, an orthographic projection of the first via on the substrate is within an orthographic projection of the first bridge electrode on the substrate, and one end of the jumper portion is connected to the first bridge electrode through the first via; and
a second bridge electrode is disposed at the end, going away from the connection line segment, of the second adapter line segment, an orthographic projection of the second via on the substrate is within an orthographic projection of the second bridge electrode on the substrate, and the other end of the jumper portion is connected to the second bridge electrode through the second via.

15. The array substrate according to claim 14, wherein chamfers are formed at corners of the first bridge electrode and the second bridge electrode.

16. The array substrate according to claim 1, wherein in the connection portion, fillets are formed at both a connection between the connection line segment and the first adapter line segment and a connection between the connection line segment and the second adapter line segment.

17. A liquid crystal display panel, comprising: an array substrate and a color film substrate that are arranged opposite to each other, and a liquid crystal layer between the array substrate and the color film substrate; wherein the array substrate comprises:
a substrate;
a plurality of gate lines and a plurality of sub-pixels arranged in arrays, which are disposed on a side of the substrate, wherein a row of the sub-pixels is electrically connected to a same gate line; wherein
the gate line comprises a plurality of connection portions and a plurality of jumper portions, wherein the plurality of connection portions and the plurality of jumper portions are alternately arranged, and the connection portions and the jumper portions are disposed in different layers; wherein
the connection portion comprises a connection line segment, a first adapter line segment, and a second adapter line segment that are disposed in a same layer and made of a same material, wherein one end of the connection line segment is connected to the first adapter line segment and the other end of the connection line segment is connected to the second adapter line segment, and an extension direction of the connection line segment is intersected with an extension direction of the first adapter line segment and intersected with an extension direction of the second adapter line segment; and
for the jumper portion between adjacent two of the connection portions, one end of the jumper portion is connected to an end, going away from the connection line segment, of the first adapter line segment in one of the connection portions, and the other end of the jumper portion is connected to an end, going away from the connection line segment, of the second adapter line segment in the other of the connection portions, and an extension direction of at least a portion of the jumper portion is intersected with the extension direction of the connection line segment.

18. The liquid crystal display panel according to claim 17, wherein the color film substrate comprises a black matrix, wherein an orthographic projection of the jumper portion of the array substrate on the substrate is within an orthographic projection of the black matrix on the substrate.

19. The liquid crystal display panel according to claim 17, wherein in the connection portion, the first adapter line segment and the second adapter line segment are respectively disposed on two sides of the connection line segment.

20. The liquid crystal display panel according to claim 19, wherein in the connection portion, the extension direction of the first adapter line segment is parallel to the extension direction of the second adapter line segment.
